(19) United States
(12) Patent Application Publication
(10) Pub. No.: US 2014/0053777 A1
(43) Pub. Date: Feb. 27, 2014

(54) VAPOR DEPOSITION APPARATUS

(71) Applicant: SAMSUNG DISPLAY CO., LTD., Yongin-si (KR)

(72) Inventors: Jai-Hyuk Choi, Yongin-si (KR); Myung-Soo Huh, Yongin-si (KR); Choel-Min Jang, Yongin-si (KR); Dong-Kyun Ko, Yongin-si (KR); In-Kyu Kim, Yongin-si (KR); Sung-Hun Key, Yongin-si (KR)

(73) Assignee: SAMSUNG DISPLAY CO., LTD., Yongin-si (KR)

(21) Appl. No.: 13/689,638

(22) Filed: Nov. 29, 2012

(30) Foreign Application Priority Data
Aug. 23, 2012 (KR) 10-2012-0092544

(51) Int. Cl. C23C 16/50

(52) U.S. Cl. CPC C23C 16/50
USPC 118/719

(57) ABSTRACT

A vapor deposition apparatus that includes a first region having a first injecting unit for injecting a first raw material and a second region having a second injecting unit for injecting a second raw material, wherein the second injecting unit comprises a plasma generation unit, wherein the plasma generation unit comprises a plasma generator, a corresponding surface surrounding the plasma generator, and a plasma generation space formed between the plasma generator and the corresponding surface, and wherein distances between the plasma generator and the corresponding surface periodically vary along an outer circumference of the plasma generator. In the vapor deposition apparatus, the quality of thin film is increased by forming stable volume plasma through set positions where the plasma is generated in the plasma generation space.

### CROSS-REFERENCE TO RELATED PATENT APPLICATION

This application claims priority to and the benefit of Korean Patent Application No. 10-2012-0092544, filed on Aug. 23, 2012, in the Korean Intellectual Property Office, the disclosure of which is incorporated herein in its entirety by reference.

### BACKGROUND

1. Field

The following description relates to a vapor deposition apparatus.

2. Description of the Related Art

Semiconductor devices, display devices, and other electronic devices may include a plurality of thin films. Various suitable methods may be used to form the thin films, one of which is a vapor deposition method. The vapor deposition method uses at least one gas as a raw material to form the thin films. Here, the vapor deposition method may include a chemical vapor deposition (CVD) method, an atomic layer deposition (ALD) method, or the like.

According to the ALD method, after a raw material is injected and purged/pumped, a single layer or a composite layer is adsorbed to a substrate, and then another raw material is injected using plasma and purged/pumped, so that a desired single or composite atomic layer is formed.

Plasma is formed by applying a voltage between a first electrode having a bar shape and a second electrode that has a cylindrical shape and is located outside the first electrode with a flow of a gas between the first and second electrodes. At this point, if minute protrusions are irregularly formed on surfaces of the electrodes, a rapid ionization of the gas may locally occur, and thus, an arc discharge may be generated. The arc discharge may deteriorate the uniformity of an atomic layer formed on the substrate.

### SUMMARY

An aspect of an embodiment of the present invention is directed toward a vapor deposition apparatus that generates uniform plasma.

According to an embodiment of the present invention, there is provided a vapor deposition apparatus for depositing a thin film on a substrate, the vapor deposition apparatus including: a first region having a first injecting unit for injecting a first raw material and a second region having a second injecting unit for injecting a second raw material, wherein the second injecting unit includes a plasma generation unit, wherein the plasma generation unit includes a plasma generator, a corresponding surface surrounding the plasma generator, and a plasma generation space formed between the plasma generator and the corresponding surface, and wherein distances between the plasma generator and the corresponding surface periodically vary along an outer circumference of the plasma generator.

A plurality of protrusions may be formed on a surface of the plasma generator, and the protrusions may form a regular pattern.

A plurality of protrusions may be formed on the corresponding surface, and the protrusions may form a regular pattern.

A plurality of first protrusions may be formed on a surface of the plasma generator, and a plurality of second protrusions may be formed on the corresponding surface, wherein the first protrusions and the second form a regular pattern.

The first protrusions and the second protrusions may be located to directly face each other.

The plasma generator may rotate and the generation of plasma may be automatically stopped at a position where the first protrusions and the second protrusions directly face each other.

The first protrusions and the second protrusions may be located alternately.

The first region may include a first purging unit for injecting a purge gas, and a first exhausting unit for performing a pumping operation and disposed between the first injecting unit and the first purging unit.

The vapor deposition apparatus may further include a first curtain unit disposed between the first purging unit of the first region and the second injecting unit of the second region.

The second region may include a second purging unit for injecting a purge gas and a second exhausting unit for performing a pumping operation and disposed between the second injecting unit and the second purging unit.

The second region may further include a second curtain unit and the second purging unit may be disposed between the second exhausting unit and the second curtain unit.

The second injecting unit further includes a plurality of slits arrayed in one direction and formed to pass the second raw material in a radical form generated in the plasma generation space.

According to another embodiment of the present invention, there is provided a vapor deposition apparatus including: a plurality of first regions that each includes a first injecting unit for injecting a first raw material, a first purging unit for injecting a purge gas, and a first exhausting unit for performing a pumping operation and disposed between the first injecting unit and the first purging unit; and a plurality of second regions that each includes a second injecting unit for injecting a second raw material, a second purging unit for injecting a purge gas, and a second exhausting unit for performing a pumping operation and disposed between the second injecting unit and the second purging unit, wherein the second injecting unit includes a plasma generation unit, wherein the plasma generation unit includes a plasma generator, a corresponding surface surrounding the plasma generator, and a plasma generation space formed between the plasma generator and the corresponding surface, and wherein protrusions are formed on at least one of a surface of the plasma generator or the corresponding surface.

The protrusions may form a regular pattern.

The protrusions may include first protrusions formed on the surface of the plasma generator, and second protrusions formed on the corresponding surface, wherein the first protrusions and the second protrusions may form a regular pattern.

The first protrusions and the second protrusions may be formed to directly face each other.

The plasma generator may rotate and the generation of plasma may be automatically stopped at a position where the first protrusions and the second protrusions directly face each other.

The first protrusions and the second protrusions may be located alternately.

The second injecting unit further includes a plurality of slits arrayed in one direction and formed to pass the second raw material in a radical form generated in the plasma generation space.

The vapor deposition apparatus may further include: a first curtain unit disposed between the first purging unit of the first region and the second injecting unit of the second region; and a second curtain unit disposed between the second purging unit of the second region and the first injecting unit of the first region.

The first regions and the second regions may be alternately disposed with each other.

In the vapor deposition apparatus according to an embodiment, the quality of thin film is increased by forming stable volume plasma through set or predetermined positions where the plasma is generated in the plasma generation space.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a vapor deposition apparatus according to an embodiment of the present invention;

FIG. 2 is a magnified view of P of FIG. 1;

FIG. 3 is a schematic drawing of slits of the vapor deposition apparatus of FIG. 1, according to an embodiment of the present invention; and

FIGS. 4 through 6 are modified versions of the plasma generation unit of the vapor deposition apparatus of FIG. 1, according to embodiments of the present invention.

### DETAILED DESCRIPTION

While exemplary embodiments are capable of various modifications and alternative forms, embodiments thereof are shown by way of example in the drawings and will herein be described in more detail. It should be understood, however, that there is no intent to limit exemplary embodiments to the particular forms disclosed, but on the contrary, exemplary embodiments are to cover all modifications, equivalents, and alternatives falling within the scope of the invention. In describing the present invention, when descriptions with respect to related known function and configuration may make the scope of the present invention unclear, the descriptions thereof will be omitted.

It will be understood that, although the terms first, second, etc. may be used herein to describe various elements, regions, and/or parts, these elements, regions, and/or parts should not be limited by these terms. These terms are only used to distinguish one element from another, and not denote sequence, up and down, or superiority.

The terminology used herein is for the purpose of describing particular embodiments only and is not intended to be limiting of the invention. The singular forms include the plural forms unless the context clearly indicates otherwise. It will further be understood that the terms “comprise” and/or “comprising” when used in this specification, specify the presence of stated features, integers, operations, elements, and/or components, but do not preclude the presence or addition of one or more other features, integers, operations, elements, components, and/or groups thereof. As used herein, the term “and/or,” includes any and all combinations of one or more of the associated listed items.

Hereafter, the present invention will be described more fully with reference to the accompanying drawings, in which exemplary embodiments of the present invention are shown.

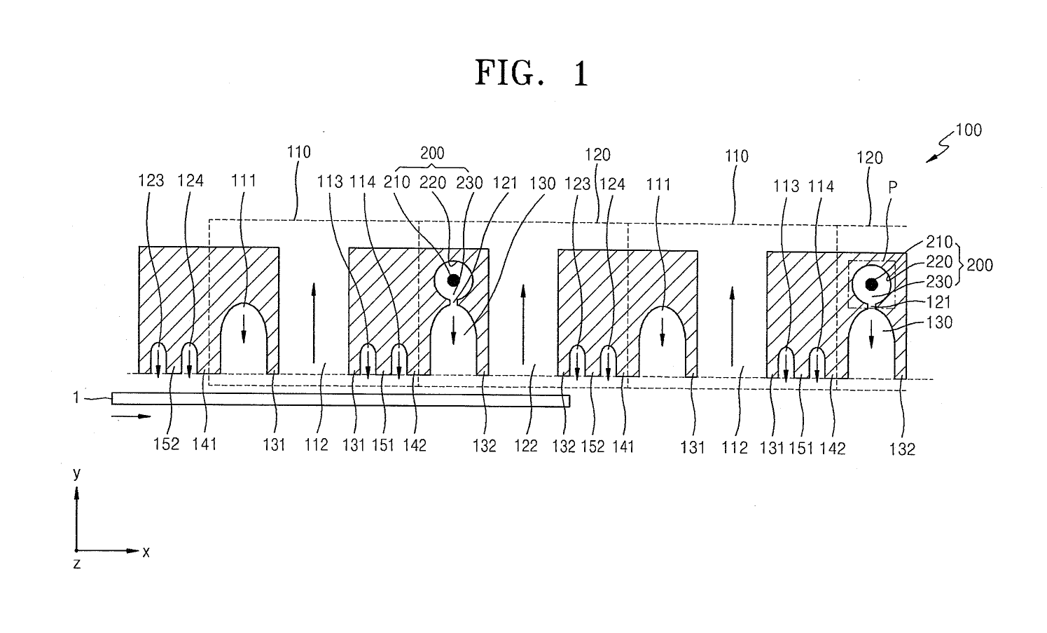

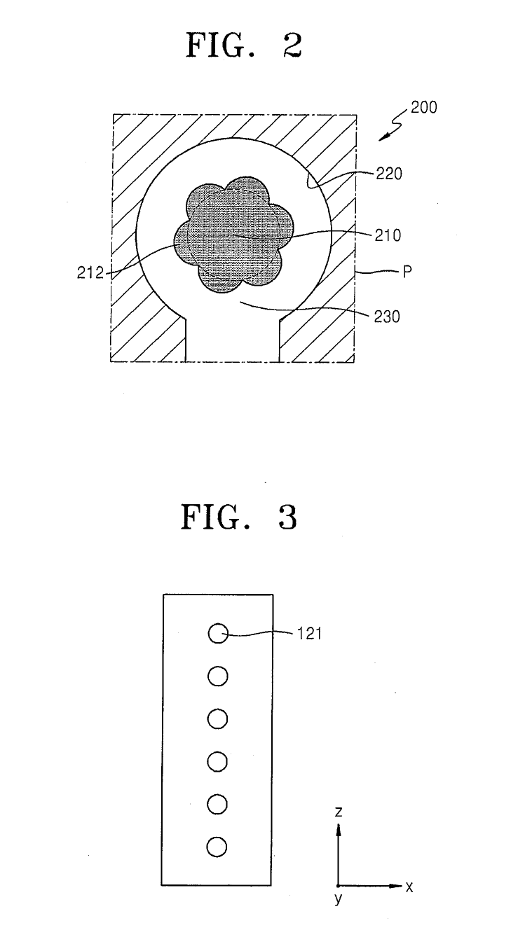

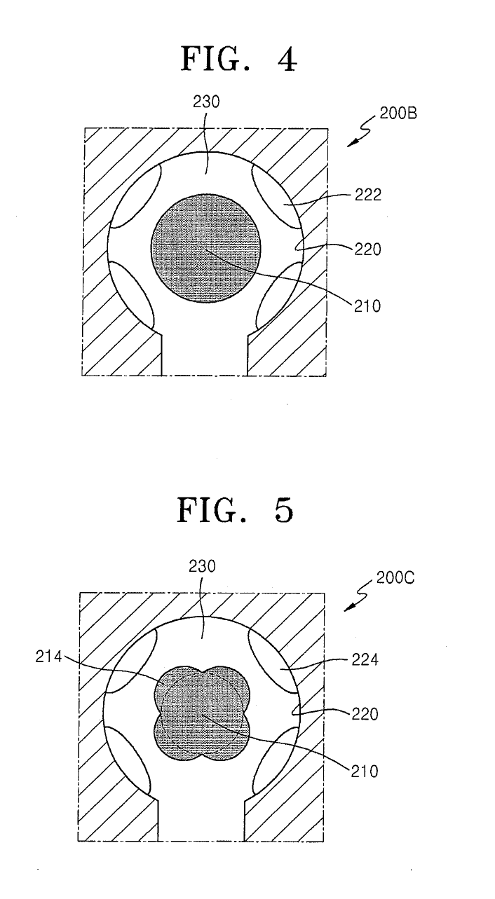

FIG. 1 is a schematic cross-sectional view of a vapor deposition apparatus 100 according to an embodiment of the present invention. FIG. 2 is a magnified view of P of FIG. 1. FIG. 3 is a schematic drawing of slits of the vapor deposition apparatus of FIG. 1.

Referring to FIG. 1, the vapor deposition apparatus 100 includes a first region 110 and a second region 120. The first region 110 and the second region 120 respectively may be formed in plural numbers, and may be alternately disposed with each other.

Also, on a lower side of the vapor deposition apparatus 100, a substrate 1 is sequentially moved under the first region 110 and the second region 120 by relatively moving with respect to the vapor deposition apparatus 100. For example, the substrate 1 may move in an X direction and a desired thin film may be formed on the moving substrate 1 by using the vapor deposition apparatus 100.

The first region 110 may include a first injecting unit 111, a first exhausting unit 112, a first purging unit 113, and a first curtain unit 114.

The first injecting unit 111 injects a first raw material for a deposition. More specifically, the first injecting unit 111 injects a gas type first raw material in a direction towards the substrate 1.

The first purging unit 113 injects a purge gas towards the substrate 1. The first purging unit 113 injects a gas that does not affect the deposition, for example, an argon gas or a nitrogen gas towards the substrate 1.

The first exhausting unit 112 is disposed between the first injecting unit 111 and the first purging unit 113. The first exhausting unit 112 pumps a physical adsorption layer that is separated from the substrate 1 by a purge gas in a direction indicated by arrows in FIG. 1.

The first curtain unit 114 is formed close to the second region 120. The first curtain unit 114 injects a curtain gas that may be an inert gas that does not affect the deposition process. The first curtain unit 114 is formed close to the second region 120 to block a material that is generated in the first region 110 or is injected to the first region 110 from penetrating into the second region 120 during a deposition process, and also, to block a material that is generated in the second region 120 or is injected to the second region 120 from penetrating into the first region 110.

A first blocking unit A 131 is formed to separate the first exhausting unit 112 from the first injecting unit 111 and the first exhausting unit 112 from the first purging unit 113, which are adjacent to each other. That is, the first exhausting unit 112 and the first injecting unit 111 do not have a common region, and also, the first exhausting unit 112 and the first purging unit 113 do not have a common region.

Also, in order to separate the first injecting unit 111 from adjacent other gas injecting units, for example, a second curtain unit 124 formed on a left side of the first region 110, a second blocking unit A 141 may be formed between the first injecting unit 111 and the second curtain unit 124 disposed on the left side of the first region 110. Also, in order to separate the first purging unit 113 from the first curtain unit 114 that is adjacent to the first purging unit 113, a third blocking unit A 151 may be formed between the first purging unit 113 and the first curtain unit 114.

The second region 120 may include a second injecting unit 130, a second exhausting unit 122, a second purging unit 123, and the second curtain unit 124.

The second injecting unit 130 injects a second raw material for deposition. Also, the second injecting unit 130 includes a plasma generation unit 200 for generating plasma.

FIG. 2 shows a magnified version of the plasma generation unit 200. Referring to FIG. 2, the plasma generation unit 200 may include a plasma generator 210, a corresponding surface 220, and a plasma generation space 230 formed between the plasma generator 210 and the corresponding surface 220.

The plasma generator 210 may be an electrode to which a voltage is applied. Also, the corresponding surface 220 is formed to surround the plasma generator 210, and may be a grounded electrode. However, the present invention is not limited thereto, and the plasma generator 210 may be grounded and a voltage may be applied to the corresponding surface 220.

Distances between the plasma generator 210 and the corresponding surface 220 periodically vary according to an outer circumference of the plasma generator 210.

For example, as depicted in FIG. 2, a plurality of protrusions 212 may be formed on a surface of the plasma generator 210. The protrusions 212 extend in a length direction of the plasma generator 210 and may be formed as one body with the plasma generator 210. Also, the protrusions 212 form a periodical pattern with the same shape relative to each other.

Each of the protrusions 212 may include a curved surface having a set or predetermined curvature. If each of the protrusions 212 has a curved surface having the set or predetermined curvature, electric field is concentrated on each of the uppermost points, and then, a discharge similar to a pin-to-plane corona discharge may occur between the protrusions 212 and the corresponding surface 220. That is, as it is seen from the Warburg's law, the largest discharge current is generated at a position where a distance between the uppermost point of one of the protrusions 212 and the corresponding surface 220 is the smallest. The longer the distance between the uppermost point of the protrusion 212 and the corresponding surface 220, the lower the value of the discharge current.

Also, a position of the corresponding surface 220 that corresponds to a region between the two adjacent protrusions 212 may be an overlapping region of a discharge current that is generated by the two protrusions 212. The value of the discharge current may be controlled by presetting a plasma generation position in consideration of intensity of a current applied to the plasma generator 210 and a distance between the plasma generator 210 and the corresponding surface 220.

Accordingly, the current may have a constant value at each position of the corresponding surface 220 by forming the protrusions 212 that determine the positions of plasma generation on a set or predetermined surface of the plasma generator 210, and thus, a stable volume plasma may be formed in the plasma generation space 230 formed between the plasma generator 210 and the corresponding surface 220.

Also, when the plasma generator 210 has a rod shape, the generation of an arc that may occur due to minute protrusions formed on a surface of the plasma generator 210 may be minimized by artificially forming the plural protrusions 212 on the plasma generator 210.

The plasma generator 210 may rotate in a direction, and accordingly, the plasma is uniformly distributed in the plasma generation space 230, and arc generation is prevented or reduced in the plasma generation space.

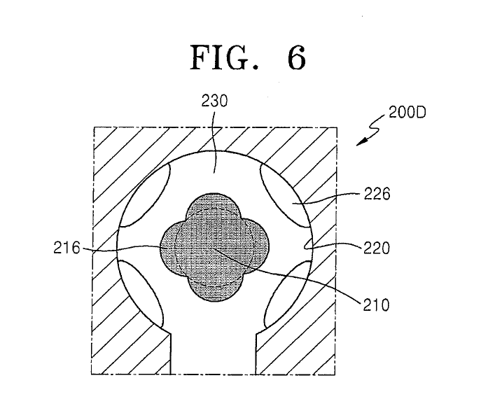

The same effect of the vapor deposition apparatus 100 described above may be applied to modified versions of plasma generators which will be described below with reference to FIGS. 4 through 6.

A second raw material is injected from an upper side of the plasma generation unit 200 and has a radical form after passing through plasma. The radical form second raw material is moved towards the substrate 1 through slits 121.

FIG. 3 shows the slits 121 of the vapor deposition apparatus 100. Referring to FIG. 3, the slits 121 may be formed in plural numbers in a length direction of the plasma generator 210 with set or predetermined distances from each other. The second raw material in a radical form that is generated in the plasma generation space 230 may be uniformly supplied onto the substrate 1 through the slits 121 without locally concentrating in the second injecting unit 130. Here, in FIG. 3, the slits 121 have a circular shape having the same size, but are not limited thereto, that is, the slits 121 according to the current embodiment may have various suitable sizes and shapes.

Referring to FIG. 1, the second purging unit 123 injects a purge gas towards the substrate 1. The second purging unit 123 injects a gas, for example, an argon gas or a nitrogen gas that does not affect the deposition towards the substrate

The second exhausting unit 122 is disposed between the second injecting unit 130 and the second purging unit 123. After injecting the second raw material from the second injecting unit 130 towards the substrate 1, a purge gas is injected towards the substrate 1 through the second purging unit 123. Afterwards, a first layer that contains the first and second raw materials may be finally formed on the substrate 1 by pumping through the second exhausting unit 122.

The second curtain unit 124 is formed close to another first region 110 that is located next to the second curtain unit 124 based on a moving direction of the substrate 1. The second curtain unit 124 injects a curtain gas that does not affect the deposition process.

Also, in the current embodiment, a deposition process is performed by a relative movement of the substrate 1 with respect to the vapor deposition apparatus 100. At this point, the second curtain unit 124 is formed close to the first region 110 located next to the second curtain unit 124 based on a moving direction of the substrate 1 to block mixing of a material generated from or injected to the second region 120 and a material generated from or injected to the first region 110 located right side of the second region 120.

Also, a first blocking unit B 132 is formed to separate the second exhausting unit 122 from the second injecting unit 130 formed adjacent to the second exhausting unit 122, and to separate the second exhausting unit 122 from the second purging unit 123. That is, the second exhausting unit 122 and the second injecting unit 130 do not have a common region, and also, the second exhausting unit 122 and the second purging unit 123 do not have a common region.

Similarly, a second blocking unit B 142 may be formed between the second injecting unit 130 and other adjacent gas injecting units, and a third blocking unit B 152 may be formed between the second purging unit 123 and the second curtain unit 124.

Hereinafter, a method of operating the vapor deposition apparatus 100 described above will be briefly described.

The substrate 1 moves in an X direction of FIG. 1 under the vapor deposition apparatus 100. For this movement, the substrate 1 is mounted on a stage, and the substrate 1 mounted on the stage may be moved through a driving unit. Also, the vapor deposition apparatus 100 may be moved in the −X direction instead of moving the substrate 1.

In the first region 110, a first raw material is injected towards the substrate 1 through the first injecting unit 111. For example, the first raw material may be a gas that contains Al atoms such as trimethyl aluminium (TMA), but not limited thereto.

A chemical adsorption layer and a physical adsorption layer are formed by the first raw material on an upper surface of the substrate 1. Of the adsorption layers formed on the upper surface of the substrate 1, the physical adsorption layer that has a weak molecular bonding force is separated from the substrate 1 by a purge gas injected from the first purging unit 113, and is effectively removed from the substrate 1 through pumping of the first exhausting unit 112. Accordingly, the purity of a deposition layer that will be finally formed on the substrate 1 may be increased.

In addition, the first blocking unit A 131 is formed between the first exhausting unit 112 and the first purging unit 113 and between the first exhausting unit 112 and the first injecting unit 111. Therefore, the pumping effect of the first exhausting unit 112 may affect the first injecting unit 111 and the first purging unit 113.

The substrate 1 sequentially moves to the second region 120, and a second raw material is injected onto the substrate 1 through the second injecting unit 130 of the second region 120. At this point, the first region 110 and the second region 120 are effectively separated by the first curtain unit 114 of the first region 110. Since the first region 110 and the second region 120 are protected (separated) from each other, the mixing of an unwanted material in each of the deposition processes is blocked.

The second raw material in a radical form that is generated from the plasma generation space 230 is injected into the second region 120.

As described above, the plasma generation space 230 is formed between the plasma generator 210 and the corresponding surface 220, and distances between the plasma generator 210 and the corresponding surface 220 are periodically changed along an outer circumference of the plasma generator 210. Therefore, plasma may be stably generated in the plasma generation space 230. Accordingly, the occurrence of an arc discharge is reduced or prevented, and thus, the uniformity of the second raw material may be increased.

The second raw material may include, for example, oxygen radicals. The oxygen radicals are formed by injecting H₂O, O₂, N₂O, etc. into the plasma generation space 230. The second raw material reacts with a chemical adsorption layer that is already formed of the first raw material by adsorbing in the substrate 1 or substitutes a portion of the chemical adsorption layer, and thus, a final desired deposition layer, for example, an AlxOy layer is formed. At this point, an excessive amount of the second raw material remains as a physical adsorption layer.

A purge gas is injected onto the substrate 1 from the second purging unit 123 to separate the physical adsorption layer remaining on the upper surface of the substrate 1. Also, the physical adsorption layer separated from the substrate 1 is effectively removed from the substrate 1 by the pumping of the second exhausting unit 122, and thus, the purity of a deposition layer to be finally formed on the substrate 1 is increased. At this point, the directionalities of the second raw material injected from the second injecting unit 130 and the purge gas injected from the second purging unit 123 are not affected by the pumping of the second exhausting unit 123 since the first blocking units B 132 are formed.

In this way, a desired single atomic layer is formed on the substrate 1 while passing through the first region 110 and the second region 120.

FIGS. 4 through 6 are modified versions of the plasma generation unit of the vapor deposition apparatus 100 of FIG. 1.

In the drawings of FIGS. 4 through 6, the plasma generator 210, the corresponding surface 220, and the plasma generation space 230 are the same as those described with reference to FIG. 2, and thus, the descriptions thereof will not be repeated, but will be described mainly with regard to the differences.

First, in the plasma generation unit 200B, the plasma generator 210 has a rod shape, and a plurality of protrusions 222 are formed on the corresponding surface 220. Thus, distances between the plasma generator 210 and the corresponding surface 220 are periodically changed along an outer circumference of the plasma generator 210.

More specifically, the protrusions 222 extend in a length direction of the plasma generator 210, may be formed as one integral body with the corresponding surface 220, and may form a regular pattern having the same shape. In particular, since the protrusions 222 include a curved surface with a set or predetermined curvature, uniform plasma may be formed in the plasma generation space 230. Also, plasma nonuniformity due to an arc discharge that occurs by minute protrusions that inevitably generated during a manufacturing process of the plasma generator 210 or the corresponding surface 220 may be reduced or minimized.

The numbers of protrusions 222 and shapes may be appropriately selected in consideration of the intensity of a current that is applied to the plasma generator 210 and the distances between the plasma generator 210 and the corresponding surface 220.

Referring to FIG. 5, first protrusions 214 are formed on a surface of the plasma generator 210 and also, matching second protrusions 224 are formed on the corresponding surface 220. Since each of the first protrusions 214 and the second protrusions 224 have a regular pattern, distances between the plasma generator 210 and the corresponding surface 220 are regularly changed along an outer circumference of the plasma generator 210.

In the plasma generation unit 200C of FIG. 5, the first protrusions 214 and the second protrusions 224 are formed to face each other (e.g., to directly face each other), and thus, positions and widths where plasma is generated are clearly seen.

The plasma generator 210 may rotate in a direction. In particular, when a voltage is applied to the plasma generator 210, the cooling of the plasma generator 210 and on/off of power as well may be controlled by the rotation of the plasma generator 210. Since an electric field E is obtained by dividing a voltage V by a distance d between two electrodes, the electric field E has a maximum value at a point where the first protrusions 214 and the second protrusions 224 directly face each other. By using this fact, the plasma generator 210 may be cooled and the generation of plasma may be automatically stopped by turning off a voltage being applied to the plasma generator 210 at the point where the first protrusions 214 and the second protrusions 224 directly face each other. However, the present invention is not limited thereto. That is, the voltage applied to the plasma generator 210 may be turned off at a point where the first protrusions 214 and the second protrusions 224 are not facing each other, e.g., when the electric field E has a minimum value.

In FIG. 6, like in FIG. 5, first protrusions 216 are formed on a surface of the plasma generator 210 and second protrusions 226 are formed on the corresponding surface 220.

However, in FIG. 6, the first protrusions 216 and the second protrusions 226 may be formed alternately.

As the first protrusions 216 and the second protrusions 226 are located alternately, uniform plasma is generated in all areas of the plasma generating space (230) and gas flow is restricted geometrically. Therefore, this type may be particularly useful when a sufficient plasma treatment or decomposition is necessary while passing through a single plasma region.

Like the plasma generation unit 200C of FIG. 5, also in the plasma generation unit 200D of FIG. 6, when a voltage is applied to the plasma generator 210, the cooling of the plasma generator 210 and the on/off of power as well may be controlled by the rotation of the plasma generator 210.

Constituent elements depicted in the drawings may be exaggerated or reduced for convenience of explanation. Therefore, the present invention should not be construed as the sizes or shapes of the constituent elements in the drawings. While the present invention has been particularly shown and described with reference to exemplary embodiments thereof, it will be understood by those of ordinary skill in the art that various changes in form and details may be made therein without departing from the spirit and scope of the present invention as defined by the following claims, and equivalents thereof.

What is claimed is:

1. A vapor deposition apparatus comprising:
a first region having a first injecting unit configured to inject a first raw material; and
a second region having a second injecting unit configured to inject a second raw material,
wherein:
the second injecting unit comprises a plasma generation unit,
the plasma generation unit comprises a plasma generator, a corresponding surface surrounding the plasma generator, and a plasma generation space formed between the plasma generator and the corresponding surface, and
distances between the plasma generator and the corresponding surface periodically vary along an outer circumference of the plasma generator.

2. The vapor deposition apparatus of claim 1, wherein a plurality of protrusions are formed on a surface of the plasma generator, and the protrusions form a regular pattern.

3. The vapor deposition apparatus of claim 1, wherein a plurality of protrusions are formed on the corresponding surface, and the protrusions form a regular pattern.

4. The vapor deposition apparatus of claim 1, wherein a plurality of first protrusions are formed on a surface of the plasma generator and a plurality of second protrusions are formed on the corresponding surface, wherein the first protrusions and the second protrusions form a regular pattern.

5. The vapor deposition apparatus of claim 4, wherein the first protrusions and the second protrusions are located to directly face each other.

6. The vapor deposition apparatus of claim 4, wherein the plasma generator is configured to rotate and automatically stop the generation of plasma at a position where the first protrusions and the second protrusions directly face each other.

7. The vapor deposition apparatus of claim 4, wherein the first protrusions and the second protrusions are located alternately.

8. The vapor deposition apparatus of claim 1, wherein the first region comprises a first purging unit configured to inject a purge gas, and a first exhausting unit configured to perform a pumping operation and disposed between the first injecting unit and the first purging unit.

9. The vapor deposition apparatus of claim 8, wherein the first region further comprises a first curtain unit disposed between the first purging unit of the first region and the second injecting unit of the second region.

10. The vapor deposition apparatus of claim 1, wherein the second region comprises a second purging unit configured to inject a purge gas and a second exhausting unit configured to perform a pumping operation and disposed between the second injecting unit and the second purging unit.

11. The vapor deposition apparatus of claim 10, wherein the second region further comprises a second curtain unit, the second purging unit being disposed between the second exhausting unit and the second curtain unit.

12. The vapor deposition apparatus of claim 1, wherein the second injecting unit further comprises a plurality of slits arrayed in one direction and formed to pass the second raw material in a radical form generated in the plasma generation space.

13. A vapor deposition apparatus comprising:
a plurality of first regions, each of the plurality of first regions comprises a first injecting unit configured to inject a first raw material, a first purging unit configured to inject a purge gas, and a first exhausting unit configured to perform a pumping operation and disposed between the first injecting unit and the first purging unit; and
a plurality of second regions, each of the plurality of second regions comprises a second injecting unit configured to inject a second raw material, a second purging unit configured to inject a purge gas, and a second exhausting unit configured to perform a pumping operation and disposed between the second injecting unit and the second purging unit,
wherein:
the second injecting unit comprises a plasma generation unit,
the plasma generation unit comprises a plasma generator, a corresponding surface surrounding the plasma generator, and a plasma generation space formed between the plasma generator and the corresponding surface, and
protrusions are formed on at least one of a surface of the plasma generator or the corresponding surface.

14. The vapor deposition apparatus of claim 13, wherein the protrusions form a regular pattern.

15. The vapor deposition apparatus of claim 13, wherein the protrusions comprise first protrusions formed on the surface of the plasma generator, and second protrusions formed on the corresponding surface, and wherein the first protrusions and the second protrusions form a regular pattern.

16. The vapor deposition apparatus of claim 15, wherein the first protrusions and the second protrusions are formed to directly face each other.

17. The vapor deposition apparatus of claim 15, wherein the plasma generator is configured to rotate and automatically stop the generation of plasma at a position where the first protrusions and the second protrusions directly face each other.

18. The vapor deposition apparatus of claim 15, wherein the first protrusions and the second protrusions are located alternately.

19. The vapor deposition apparatus of claim 13, wherein the second injecting unit further comprises a plurality of slits arrayed in one direction and configured to pass the second raw material in a radical form generated in the plasma generation space.

20. The vapor deposition apparatus of claim 13, further comprising:
a first curtain unit disposed between the first purging unit of the first region and the second injecting unit of the second region; and
a second curtain unit disposed between the second purging unit of the second region and the first injecting unit of the first region.

21. The vapor deposition apparatus of claim 13, wherein the first regions and the second regions are alternately disposed with each other.
